(19) United States
(12) Patent Application Publication
(10) Pub. No.: US 2026/0080128 A1
(43) Pub. Date: Mar. 19, 2026

(54) METHOD AND DEVICE FOR MACHINE DESIGN

(71) Applicants: Hyundai Motor Company, Seoul (KR); Kia Corporation, Seoul (KR)

(72) Inventor: Yong Uk SHIN, Hwaseong-Si (KR)

(21) Appl. No.: 19/325,959

(22) Filed: Sep. 11, 2025

(30) Foreign Application Priority Data
Sep. 13, 2024 (KR) 10-2024-0125873

(51) Int. Cl. G06F 30/27; G06F 30/17; G06T 11/20

(52) U.S. Cl. CPC G06F 30/27; G06F 30/17; G06T 11/26

(57) ABSTRACT

A method performed by an apparatus may comprise defining a Markov decision process (MDP) for use in deep reinforcement learning associated with gear train topology, representing the gear train topology based on the MDP, generating the gear train topology through deep reinforcement learning of a deep Q-network (DQN), and constructing a gear train based on the generated gear train topology.

### CROSS-REFERENCE TO RELATED APPLICATION

This application claims the benefit of priority to Korean Patent Application No. 10-2024-0125873 filed in the Korean Intellectual Property Office on Sep. 13, 2024, the entire contents of which are incorporated herein by reference.

### TECHNICAL FIELD

The present disclosure relates to a method and a device for machine design.

### BACKGROUND

The matters described in this Background section are only for enhancement of understanding of the background of the disclosure, and should not be taken as acknowledgment that they correspond to prior art already known to those skilled in the art.

In a machine design field, designers may use schematic diagrams through dots and lines using their own experience and mechanical knowledge in concept design. Some proposed methods may include a multi-stage transmission synthesis method using an exercise equation of a planetary gear set, and a convergence transmission synthesis method for reviewing all combinations of a planetary gear and an external gear arrangement in a fixed shaft. Some methods may proceed by exploring all possible structures, and require a full survey and exploration to find a desired structure. In particular, in the case of a complex structure, the number of cases is too large, so it may not be practical to explore the structure. In addition, it may be difficult to derive a new mode of mechanical structure because a structure may be explored only in a limited state.

Although the generated artificial intelligence has evolved rapidly, artificial intelligence models have limits for deriving results that require accuracy of mechanical structures based on physical phenomena. Thus, the generated artificial intelligence may not be suitable for deriving the concept design of the machine structure. On the other hand, in the field of robotics, a method of designing a robot arm using deep reinforcement learning with a combination of a rod and a motor may be considered, but such method may also be limited only in a specific form such as the robot arm, thus difficult to apply such method to general a mechanical connection structure (machine topology). For this reason, a new method to be more effective and generalized in mechanical structure design is considered.

### SUMMARY

The present disclosure attempts to provide a method and a device for machine design capable of providing synthesis of gear train topology based on artificial intelligence technology.

According to the present disclosure, a method performed by an apparatus, the method may comprise, defining a Markov decision process (MDP) for use in deep reinforcement learning associated with gear train topology, representing, based on the MDP, the gear train topology, generating the gear train topology through deep reinforcement learning of a deep Q-network (DQN), and constructing, based on the generated gear train topology, a gear train. The method, wherein the defining of the MDP may comprise, defining an action as adding an edge to a graph, defining a state as a graph resulting from performing the action, and defining a weight value indicating whether a condition associated with a graph representing the gear train topology is satisfied.

The method, wherein a node of the graph represents a component of the gear train, and an edge of the graph represents a type of a connection between components of the gear train, wherein the state is expressed as a state tensor defined from a state space, and wherein the state space represents graph configurations of gear train topologies. The method, wherein the generating of the gear train topology may comprise, generating, based on one or more design constraints for the gear train topology, a representation of a candidate gear train topology, iteratively modifying the representation using a machine learning model, wherein each modification is performed based on whether the modified representation satisfies the one or more design constraints, and outputting data representing the gear train topology that satisfies the one or more design constraints.

The method, wherein the representing of the gear train topology may comprise converting a structure synthesis process into a tree search process. The method, wherein the DQN is implemented to alternately use a plurality of convolutional layers and Rectified Linear Unit (ReLU) activation functions, and apply a fully connected layer. The method, wherein, an input of the DQN may comprise a tensor representing a graph of the gear train topology, wherein the tensor is transformed to a state tensor, and an output of the DQN may comprise an edge vector represented as a one-hot vector, wherein the edge vector identifies a candidate connection between components in the gear train topology.

The method, wherein the input of the DQN passes through a first ReLU activation function followed by a first convolutional layer, passes through a second ReLU activation function followed by a second convolutional layer, passes through a third ReLU activation function followed by a third convolutional layer, and passes through a fourth ReLU activation function followed by a fully connected layer. The method, wherein the deep reinforcement learning may comprise performing an action of adding the edge vector to the graph. The method, wherein the generating of the gear train topology may comprise, classifying, based on a predetermined classification criterion, a gear train topology graph into one or more types, wherein the gear train topology graph is generated by the deep reinforcement learning, and generating, based on the classified type of gear train topology graph, a gear train schematic diagram.

According to the present disclosure, an apparatus may comprise, a processor, and a memory storing at least one instruction that, when executed by the processor communicating with the memory, is configured to cause the apparatus to, define a Markov decision process (MDP) for use in deep reinforcement learning associated with gear train topology, represent, based on the MDP, the gear train topology, generate the gear train topology through deep reinforcement learning of a deep Q-network (DQN), and construct, based on the generated gear train topology, a gear train. The apparatus, wherein the at least one instruction, when executed by the processor communicating with the memory, is configured to cause the apparatus to define the MDP by, defining an action as adding an edge to a graph, defining a state as a graph resulting from performing the action, and defining a weight value indicating whether a condition associated with a graph representing the gear train topology is satisfied.

The apparatus, wherein a node of the graph represents a component of the gear train, and an edge of the graph represents a type of a connection between components of the gear train, wherein the state is expressed as a state tensor defined from a state space, and wherein the state space represents graph configurations of gear train topologies. The apparatus, wherein the at least one instruction, when executed by the processor communicating with the memory, is configured to cause the apparatus to generate the gear train topology by, generating, based on one or more design constraints for the gear train topology, a representation of a candidate gear train topology, iteratively modifying the representation using a machine learning model, wherein each modification is performed based on whether the modified representation satisfies the one or more design constraints, and outputting data representing the gear train topology that satisfies the one or more design constraints.

The apparatus, wherein the at least one instruction, when executed by the processor communicating with the memory, is configured to cause the apparatus to represent the gear train topology by converting a structure synthesis process into a tree search process. The apparatus, wherein the DQN is implemented to alternately use a plurality of convolutional layers and Rectified Linear Unit (ReLU) activation functions, and apply a fully connected layer. The apparatus, wherein, an input of the DQN may comprise a tensor representing a graph of the gear train topology, wherein the tensor is transformed to a state tensor, and an output of the DQN may comprise an edge vector represented as a one-hot vector, wherein the edge vector identifies a candidate connection between components in the gear train topology.

The apparatus, wherein the input of the DQN passes through a first ReLU activation function followed by a first convolutional layer, passes through a second ReLU activation function followed by a second convolutional layer, passes through a third ReLU activation function followed by a third convolutional layer, and passes through a fourth ReLU activation function followed by a fully connected layer.

According to the present disclosure, a method performed by an apparatus, the method may comprise, obtaining data representing one or more design constraints for a gear train topology, generating, based on the obtained data, a representation of a candidate gear train topology, iteratively modifying the representation using a machine learning model, wherein each modification is performed based on whether the modified representation satisfies one or more design constraints, outputting data representing a gear train topology that satisfies the one or more design constraints, and constructing a gear train based on the outputted data representing the gear train topology.

The method, wherein, the representation may comprise a graph having a plurality of nodes and edges, wherein each node represents a mechanical component and each edge represents a type of connection between two nodes of the plurality of nodes, and the machine learning model may comprise a neural network configured to select a modification to the graph based on whether the modified graph satisfies the one or more design constraints.

### BRIEF DESCRIPTION OF THE DRAWINGS

FIG. 1 shows an example of a device for machine design according to an example.

FIG. 2 shows an example of a method for machine design according to an example.

FIG. 3A, FIG. 3B, FIG. 4A, FIG. 4B, FIG. 4C, FIG. 5, FIG. 6, FIG. 7, FIG. 8, FIG. 9, FIG. 10A, FIG. 10B, FIG. 10C, and FIG. 11 show exemplary implementation of machine design according to examples.

FIG. 12 shows an example of a computing device according to an example.

### DETAILED DESCRIPTION

examples of the present disclosure will be described more fully hereinafter with reference to the accompanying drawings, in which examples of the disclosure are shown. As those skilled in the art would realize, the described examples may be modified in various different ways, all without departing from the spirit or scope of the present disclosure. Accordingly, the drawings and description are to be regarded as illustrative in nature and not restrictive. Like reference numerals designate like elements throughout the specification.

Throughout the specification and claims, unless explicitly described to the contrary, the word “comprise”, and variations such as “comprises” or “comprising”, will be understood to imply the inclusion of stated elements but not the exclusion of any other elements. Terms including an ordinary number, such as first and second, are used for describing various constituent elements, but the constituent elements are not limited by the terms. The terms are used only to discriminate one component from another component.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

In addition, terms including “part’, “˜er”, “module”, and the like disclosed in the specification mean a unit that can process at least one function or operation described in this specification and this may be implemented by hardware or a circuit, or software or a combination of hardware or the circuit and software. Further, at least some components or functions of a method and a device for machine design according to examples described below may be implemented as a program or software, and the program or software may be stored in a computer readable medium.

The term “module” or “unit” used in the specification means a software and/or hardware component, and the “module” or “unit” performs certain operations/functions/roles. However, the “module” or “unit” is not construed as being limited to software or hardware. The “module” or “unit” may be configured to be in an addressable storage medium or to execute one or more processors. Therefore, as an example, the “module” or “unit” may include at least one of components such as software components, object-oriented software components, class components, and task components, processes, functions, attributes, procedures, sub-routines, segments of program codes, drivers, firmware, micro-codes, circuits, data, databases, data structures, tables, arrays, or variables. Functions provided in the components, “modules”, or “units” may be combined into a smaller number of components, “modules”, or “units” or further divided into additional components, “modules”, or “units”.

In the present disclosure, the “module” or “unit” may be realized as a processor and a memory. The “processor” should be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like. For example, the “processor” may refer to a combination of processing devices such as a combination of a DSP and a microprocessor, a combination of a plurality of microprocessors, a combination of one or more microprocessors combined with a DSP core, or any other such combination. Moreover, the “memory” should be widely construed to include any electronic component capable of storing electronic information. The “memory” may refer to various types of processor-readable medium such as a random access memory (RAM), a read only memory (ROM), a non-volatile random access memory (NVRAM), a programmable read only memory (PROM), an erasable programmable read only memory (EPROM), an electrically erasable programmable read only memory (EEPROM), a flash memory, a magnetic or optical data storage device, and registers. When the processor can read information from a memory and/or record the information in the memory, the memory may be in a state of electronic communication with a processor. Memory integrated into a processor is in a state of electronic communication with the processor.

The one or more features described herein may be provided as a computer program stored in a computer-readable recording medium in order to be executed on a computer. The medium may either continuously store a computer-executable program or temporarily store the program for execution or download. Furthermore, the medium may be a variety of recording or storage means in the form of a single hardware device or multiple combined hardware devices, and is not limited to media directly connected to some computer system but may also be distributed across a network. Examples of such media include magnetic media such as a hard disk, a floppy disk, or a magnetic tape, optical recording media such as a CD-ROM or a DVD, magneto-optical media such as a floptical disk, and a ROM, RAM, or flash memory, among others, configured to store program instructions. Additional examples of such media include media or storage media that are managed by an app store that distributes applications or by various other sites or servers that provide or distribute software.

In a hardware implementation, processing units used for performing the techniques may be implemented within one or more ASICs, DSPs, digital signal processing devices, programmable logic devices, field-programmable gate arrays, processors, controllers, microcontrollers, microprocessors, electronic devices, or computers or combinations thereof designed to perform the functions described in the present disclosure.

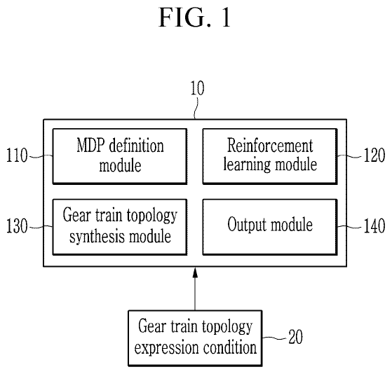

FIG. 1 shows an example of a device for machine design according to an example.

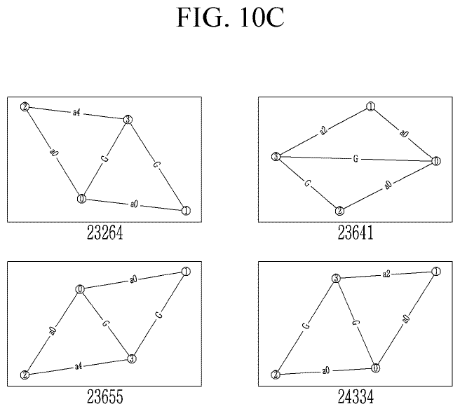

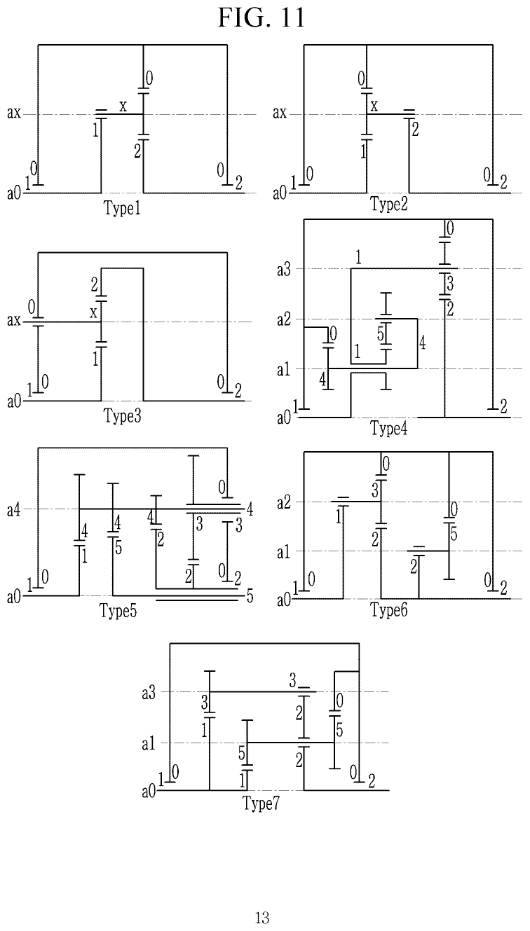

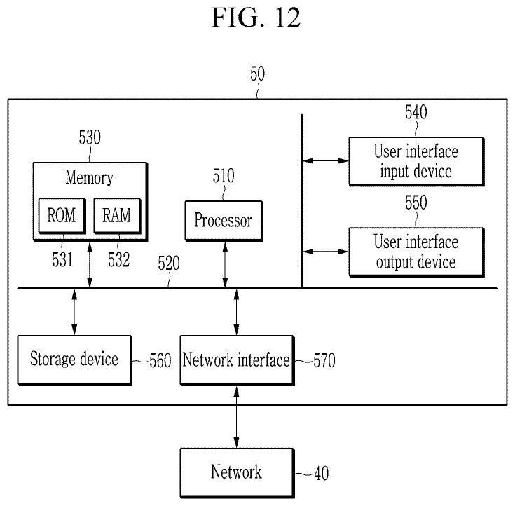

Referring to FIG. 1, the machine design device 10 according to an example may execute program codes or instructions loaded on one or more memory devices through one or more processors. For example, the machine design device 10 may be implemented as a computing device 50 described below in relation to FIG. 12. In this case, one or more processors may correspond to a processor 510 of the computing device 50, and one or more memory devices may correspond to a memory 530 of the computing device 50. A program code or an instruction is executed by one or more processors to generate a gear train topology based on deep reinforcement learning. In this specification, the term “module” is used to logically distinguish the functions of performing the program code or instruction.

The deep reinforcement learning may be a machine learning technique in which reinforcement learning and a deep neural network are combined. The reinforcement learning may be a method of learning an optimal action in order to achieve a given goal as an agent interacts with an environment. The agent may attempt various actions in the environment, and may perform learning through a reward or a penalty for each action. In deep reinforcement learning, a policy or a value function of the agent may be approximated by using a deep neural network in such a reinforcement learning process. The deep neural network may learn patterns in a complex state space, and may function to make better decisions based thereon (e.g., selecting a next graph action, pruning invalid configurations, or predicting optimal connections, etc.).

A gear train may mean a mechanical system constituted by two or more gears which are engaged with each other. The gear train may be used to transmit power, and convert a rotational speed or a direction. For example, in a transmission of a vehicle, the gear train may serve to transmit a rotational force of an engine to a wheel, and adjust a speed and a torque. Various gear trains may be designed according to a size of a gear, a number of gears, gear type (e.g., spur, helical, or planetary), or a placement mode (e.g., coaxial or offset) of the gear, and each gear rotates at a predetermined ratio by engaging with another gear.

The gear train topology may mean a structural pattern that indicates how the gears are arranged and connected. Interactions among gears and a manner of power transmissions may be analyzed through the gear train topology. This may play an important role in designing various gear arrangements in order to optimize the efficiency of the machine system, and satisfy specific operation requirements. For example, in a complex gear system such as a planetary gear train, a location and a connection mode of each gear may be systematically analyzed and designed through the gear train topology (e.g., gear positioning, interconnection levels, or transfer vertices may be analyzed and designed to ensure degrees of freedom, torque flow, or constraint satisfaction, etc.).

The machine design device 10 may include an MDP definition module 110, a reinforcement learning module 120, a gear train topology synthesis module 130, and an output module 140 in order to generate the gear train topology based on deep reinforcement learning.

The MDP definition module 110 may define a Markov decision process (MDP) for applying the gear train topology to a reinforcement learning framework. The MDP may provide a mathematical framework for deciding in a current state in order to achieve a goal. The MDP may define a current state(S), an action (A), a next state (S′), and a reward (R) (e.g., a weight) according to a state change.

The state may indicate a situation of the system or environment at a specific time point. The state may include all information of the environment recognized by the agent, and this may become basic data for decision making (e.g., current graph structure, available nodes, or connection history, etc.). The action may indicate an available choice which the agent may take in the current state. In each state various actions are possible, and the next state may be determined according to the selected action. A state which the agent reaches after taking a specific action is the next state, and the MDP has a Markov property, so the next state depends only on the current state and the selected action, and may not be influenced by previous states. The reward may mean an immediate feedback which the agent receives as a result of taking a specific action in a specific state. The reward may be positive or negative, and this may become a criterion for evaluating which action is preferable in order for the agent to achieve the goal (e.g., generating a valid subgraph, satisfying topological constraints, or avoiding redundant connections, etc.).

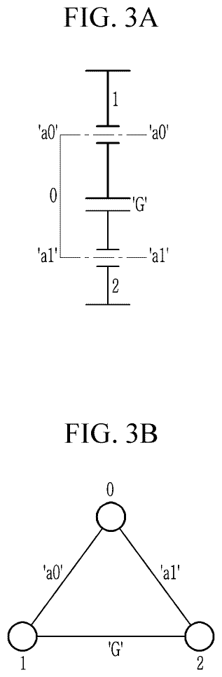

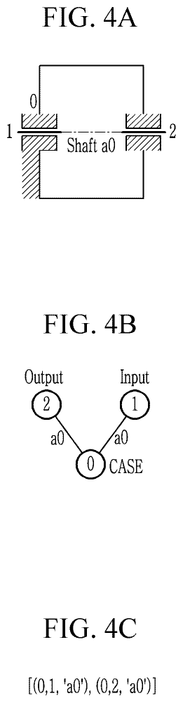

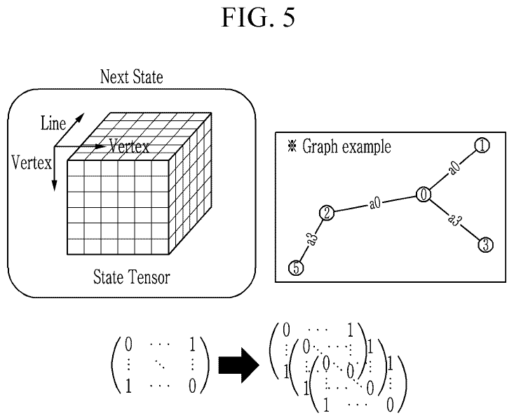

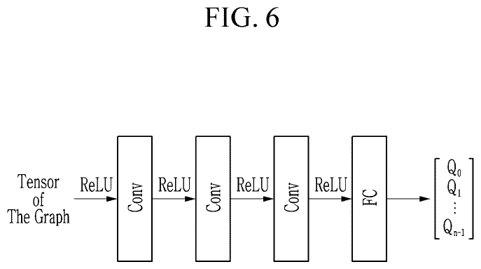

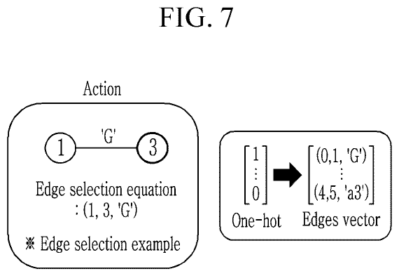

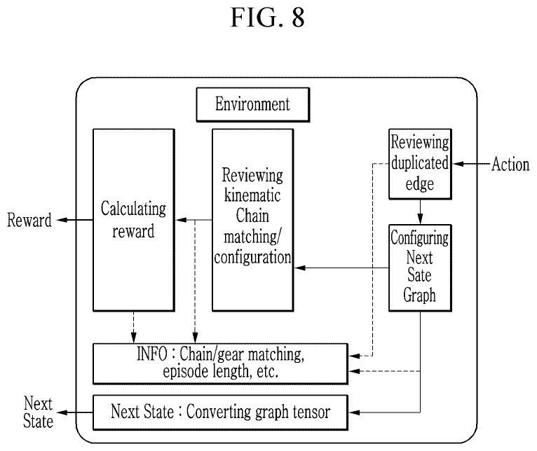

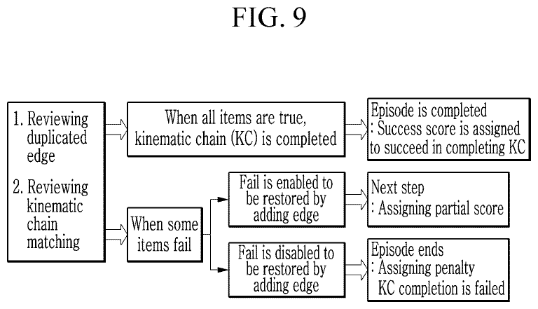

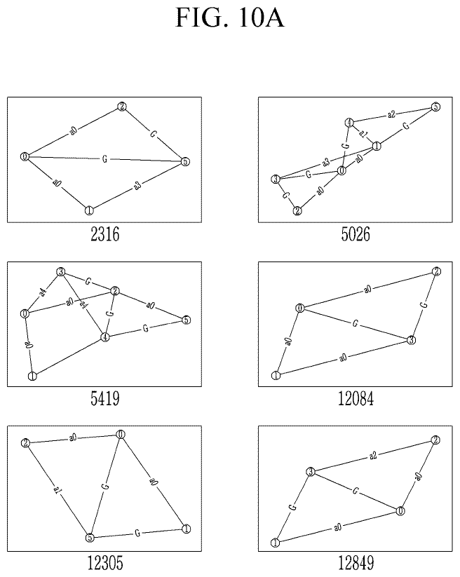

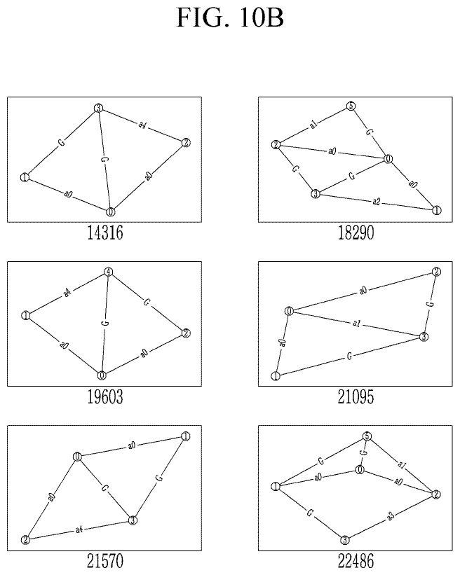

The gear train topology synthesis module 130 may express the synthesis of the gear train topology using the MDP. In this case, the goal to be achieved may be a graph of a kinematic chain which is physically meaningful (e.g., valid under mechanical design principles). For example, a final result synthesized through any series of processes as a graph of the gear train may satisfy all eight features to be described below in relation to FIGS. 3A and 3B. Hereinabove, the MDP definition module 110 may define the series of processes in forms of the action, the state, and the reward.

The gear train topology synthesis module 130 may configure the action in a manner similar to a mode of increasing an element in the existing rule based synthesis mode, and the state may be expressed in the form of the graph generated by the action. In the existing genetic graph approach, a vertex is added, and a rotating shaft or a gear connection of the element in adjacent matrices is defined, but such a mode has a problem in that the state is not confirmed by the addition of the vertex, and an additional continuous process is generated which is difficult to implement directly in an MDP mode. In order to solve this, the gear train topology synthesis module 130 fixes a dimension of the state by modifying the mode of adding a vertex to a mode of adding an edge, thereby making it easier to train a deep reinforcement learning network provided through the reinforcement learning module 120. In the case of the state, a maximum dimension may be set based on the maximum number of components, and a fixed action space dimension may be obtained, which corresponds to a dimension of a state space. In the case of the reward, compliance with required features of the gear train topology graph may be assigned as a partial score (e.g., weight value), and a graphic feature value of a single non-directional (undirected) graph is added to determine whether the graph is unsuccessful (e.g., due to invalid loops, duplicate connections, or structural violations, etc.).

For example, the gear train topology synthesis module 130 may define an action as adding an edge to a graph, define a state as a graph resulting from the action, and define a partial score (e.g., weight value) indicating whether a condition associated with the gear train topology graph is satisfied as a reward. In some examples, each node in the graph may represent a component, and each edge may represent a connection type (e.g., a rotating shaft connection, a gear meshing link, or a fixed coupling, etc.). In some examples, the state may be expressed as a multidimensional state tensor defined from the state space.

The gear train topology synthesis module 130 expresses the topology synthesis process of the gear train in an MDP format to transform a structure synthesis problem into a tree search problem, and thus applies deep reinforcement learning to efficiently perform structure generation.

The gear train topology synthesis module 130 may synthesize gear train topology through deep reinforcement learning of a deep Q-network (DQN). Here, a Q-network of the DON may be implemented to alternately use a plurality of convolutional layers and ReLU activation functions, and then apply a fully connected layer last (e.g., a 3-layer CNN followed by dense output, etc.). In some examples, an input of the Q-network may be a tensor of the graph transformed into the state tensor, and an output of the Q-network may define an edge vector in the form of a one-hot vector (e.g., indicating a connection between node 2 and node 4 via edge type ‘a1’, etc.). In some examples, in the Q-network, the input may go through a first convolutional layer after passing through a first ReLU activation function, go through a second convolutional layer after passing through a second ReLU activation function, go through a third convolutional layer after passing through a third ReLU activation function, and go through the fully connected layer after passing through a fourth ReLU activation function (e.g., for selecting one edge from a fixed-size action space, etc.). In some examples, in the deep reinforcement learning, the action may include adding to the graph an edge corresponding to the one-hot vector.

In some examples, the gear train topology synthesis module 130 may classify the gear train topology graph generated through the deep reinforcement learning of the reinforcement learning module 120 into one or more types according to a predetermined classification criterion (e.g., by number of components, types of connections, or graph isomorphism, etc.), and generate a gear train schematic diagram according to the type of gear train topology graph.

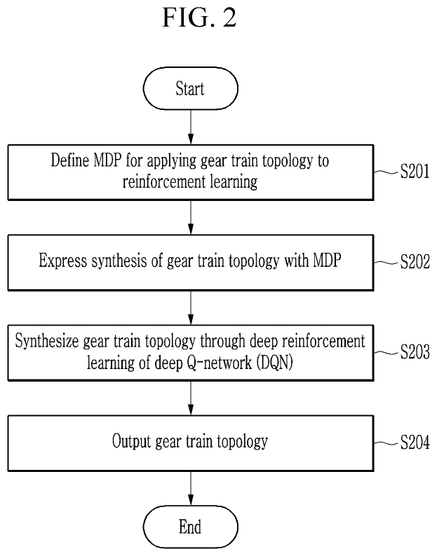

FIG. 2 shows an example of a method for machine design according to an example.

Referring to FIG. 2, the machine design method according to an example may include a step S201 of defining an MDP for applying gear train topology to reinforcement learning, a step S202 of expressing synthesis of the gear train topology with the MDP, a step S203 of synthesizing the gear train topology through deep reinforcement learning of a deep Q-network (DQN), and a step S204 of outputting the gear train topology (e.g., in schematic, graphical, or physical format, etc.).

The description of the examples described in this specification may be referenced for more detailed contents for the method, so here, a redundant description will be omitted.

FIG. 3A, FIG. 3B, FIG. 4A, FIG. 4B, FIG. 4C, FIG. 5, FIG. 6, FIG. 7, FIG. 8, FIG. 9, FIG. 10A, FIG. 10B, FIG. 10C, and FIG. 11 show exemplary implementation of machine design according to examples.

Referring to FIGS. 3A and 3B, the gear train may be possible to be expressed in function centered schematic diagram and graph formats. A fundamental gear train structure configuring the kinematic chain may connect respective components by rotating pair and geared pair. When a gear train connection structure of FIG. 3A is expressed as a graph, component 0 is connected to component 1 by a rotating shaft of ‘a0’, and connected to component 2 by a rotating shaft of ‘a1’. Component 1 and component 2 are possible to be expressed as in the graph of FIG. 3B in which the components are connected by a gear. The kinematic chain of the graph in FIG. 3B is referred to as a fundamental circuit in which complex gear train components are configured in a fundamental form. The fundamental circuit is a foundation of the gear train connection structure, and is also a fundamental component of a kinetic equation. A vertex where rotating components at both ends are changed, i.e., two different rotating components are connected in the fundamental circuit like component 0 is referred to as a transfer vertex, and corresponds to a key component constituting a feature of the fundamental circuit (e.g., serving as a carrier or central shaft, etc.). The vertex corresponds to a component corresponding to a carrier or a case in the gear train.

The graphic expression of the gear train constituted by the fundamental components may have eight following distinguished features. 1. degree of freedom F_{DOF} of the configuration system is defined as a difference between the number of rotating shaft pairs N_{rotating} and the number of geared pairs N_{gear_edge}.

$${F}_{DOF} = {N}_{rotating} - {N}_{gear \_ edge}$$

2. When all geared pair lines are removed from the graphic expression, rotating shaft pair lines form a tree (e.g., a spanning tree).

3. The number of fundamental circuits and the number of geared pairs should be equal to each other.

4. The rotating shaft pair lines are specified or identified as levels such as ‘a0’ and ‘a1’.

5. In the fundamental circuit, the number of transfer vertexes is one. Therefore, there are three edge types in the fundamental circuit (one geared pair and two rotating pair types) (e.g., one gear connection and two types of rotating shaft connections, etc.).

6. All vertexes in the graphic expression of the kinematic chain may not be connected only by the same type of edges.

7. In the rotating shaft pair, only shafts of the same type form a single tree.

8. In the graphic expression of the kinematic chain, there is no loop that is configured exclusively by the geared pair.

Only if all of the above eight conditions are satisfied, a resulting graphic expression of the gear train is considered meaningful for physical connection (e.g., realizable in hardware, compliant with motion constraints, or valid for torque transfer, etc.).

Referring to FIG. 4A, FIG. 4B, and FIG. 4C, the deep reinforcement learning of gear train synthesis may be implemented by applying the DQN mode to the MDP of the gear train synthesis. Six components (corresponding to vertexes) may be considered, and the deep reinforcement learning algorithm for the gear train synthesis may be applied to a coaxial input/output gear train topology, which comprises six pair types formed by the geared pair and the rotating shaft (e.g., G, a0, a1, a2, a3, and a4, etc.).

As illustrated in FIG. 4A, FIG. 4B, and FIG. 4C, graph synthesis may be performed to generate a gear train topology that connects an input rotating shaft and an output rotating shaft, based on an initial condition constituted by an input rotating shaft and an output rotating shaft which are coaxial (e.g., coaxially aligned, sharing a common rotational axis to simplify alignment and torque transfer, etc.). FIG. 4A illustrates a schematic diagram in which the initial condition is constituted by the input and output rotating shafts and a case, and is enabled to be configured by FIG. 4B as graphic expression. The same initial state is enabled to be input with an equation of FIG. 4C.

Referring to FIG. 5, the state space may be defined with the state tensor of FIG. 5. The dimension of each component may be constituted by up to six components of component 0 to component 5. Connection types of respective components may be constituted by lines, and defined as ‘G’, ‘a0’, ‘a1’, ‘a2’, ‘a3’, ‘a4’, and ‘a5’ (e.g., where ‘G’ represents a gear connection and ‘a0’-‘a5’ represent shaft levels, etc.). As a result, the graphic expression of the gear train may be defined as a dimension of 6×6×6 with the state tensor. For example, (0,1,‘a0’), for example, when components 0 and 1 are connected to the ‘a0’ shaft, second depths of a first row and a second column, and a second row and a first column are set to 1 by applying the connection to the state tensor.

Referring to FIG. 6, in relation to a state tensor expression mode of the graph, a structure of a Q-network of a deep reinforcement learning agent may be appreciated in the context of the state tensor representation of the graph (e.g., where node connections are encoded as multidimensional arrays for input into the network, etc.). An input of the Q-network is set as a tensor of a graph which the expression by the graph is transformed with the state tensor, and an output defines a configurable edge vector corresponding to each row in the form of the one-hot vector to allow one line to be derived in the state space as illustrated in FIG. 7 (e.g., to add an edge between two components at a specific shaft level, etc.).

As illustrated in FIG. 7, the action of the agent may be determined, and set as an input for the environment in FIG. 8. With respect to lines corresponding to input actions, it may be first be checked whether lines are duplicated in a graph of a current state. Since the graphic expression of the gear train topology is a non-directional single-line graph (a non-directed graph with single connections per edge), when a duplicated line is selected, an episode of a gear train topology configuration is ended as a failure, and a next episode may start new (e.g., to explore alternative graph paths or avoid previously failed edge insertions, etc.). After reviewing the duplicated line, matching is reviewed in relation to whether eight graphic expression features of the kinematic chain of the gear train are satisfied by configuring a graph of a next state, and a reward is calculated to proceed to a next step or complete the episode.

As illustrated in FIG. 9, if all review items are true, the episode may be completed by successfully configuring the kinematic chain that forms a physically meaningful gear train topology. When the step proceeds from the initial state of FIGS. 4A, 4B, and 4C to the action of adding the line, some constraints may initially fail in most cases. In relation to whether the next step is to proceed, if a matching failure item of a next state (or observation) changed through the action in the current state is enabled to be restored additionally in the next step, a reward for a partial score (e.g., a weight value) may be assigned, and the next step may proceed (e.g., if the violation is recoverable by adding a missing link or balancing a transfer vertex, etc.). However, if a failure condition is not resolved, the episode may end in failure, and a next new episode may proceed.

In addition, if the number of graph lines is equal to or more than a predetermined number, a penalty is added to a reward value to allow learning to be performed while suppressing excessive unnecessary connections (e.g., excessive edge density or looping structures, etc.). A DQN learning algorithm of gear train topology generation deep reinforcement learning may be implemented by using a replay memory and a target network.

FIG. 10A, FIG. 10B, and FIG. 10C illustrates a generation result of the gear train topology using the deep reinforcement learning. Here, the number may represent the episode. In FIG. 10A, FIG. 10B, and FIG. 10C, 16 results are illustrated, which satisfy all matching of the gear train topology graph expression, which may be classified into 7 types. When an isomorphic graph is classified as one type, the type of topology graph may be classified according to the number of vertexes and the type of line of the graph, and a connection mode of the vertex and the line as in Table 1 (e.g., based on structural equivalence regardless of vertex labeling, etc.). Types 1, 2, and 3 have the same numbers of vertexes and lines, but since types 1, 2, and 3 have different connection features, types 1, 2, and 3 are distinguished (e.g., varying edge distributions, different transfer vertex locations, or differing gear/shaft sequencing, etc.).

TABLE 1

| Type | Vertexes | Line type | Corresponding episodes |
|---|---|---|---|
| 1 | 4 vertexes | 3 types | 2316, 12084, 19603, |
| | | (G, a0, ax) | 23641, 24334 |
| 2 | 4 vertexes | 3 types | 12305, 12849, 14316, |
| | | (G, a0, ax) | 21570, 23264, 23655 |
| 3 | 4 vertexes | 3 types | 21095 |
| | | (G, a0, ax) | |
| 4 | 6 vertexes | 5 types | 5026 |
| | | (G, a0, a1, a2, | |
| | | a3) | |
| 5 | 6 vertexes | 3 types | 5419 |
| | | (G, a0, a4) | |
| 6 | 5 vertexes | 4 types | 18290 |
| | | (G, a0, a1, a2) | |
| 7 | 5 vertexes | 4 types | 22486 |
| | | (G, a0, a1, a3) | |

FIG. 11 illustrates a schematic diagram of the gear train topology graph according to the type. The schematic diagram is implemented according to the type of gear topology graph generated by the deep reinforcement learning (e.g., type 1 with three transfer vertices, type 2 with two geared loops, etc.).

FIG. 12 shows an example of a computing device according to an example.

Referring to FIG. 12, the method and the device for machine design according to the examples may be implemented by using the computing device 50. The computing device 50 may be implemented as various types of electronic devices and servers, or devices similar thereto, and a function of the computing device 50 may be implemented through a combination of software and hardware (e.g., embedded systems, AI inference servers, or edge computing nodes, etc.).

The computing device 50 may include at least one of a processor 510, a memory 530, a user interface input device 540, a user interface output device 550, and a storage device 560 which communicate with each other through a bus 520 (e.g., for coordinated control, data exchange, or real-time inference tasks, etc.). The computing device 50 may also include a network interface 570 electrically connected to a network 40. The network interface 570 may transmit or receive a signal to or from another entity through the network 40 (e.g., remote model training server, cloud storage, or data logger, etc.).

The processor 510 may be implemented as various types of computation devices, e.g., a micro controller unit (MCU), an application processor (AP), a central processing unit (CPU), a graphic processing unit (GPU), a neural processing unit (NPU), a quantum processing unit (QPU), or other specialized processors, etc. The processor 510 which is also a semiconductor device which executes an instruction stored in the memory 530 or the storage device 560 may perform a core role of the system. A program code and data stored in the memory 530 or the storage device 560 instructs the processor 510 to perform a specific task, and as a result, an overall operation of the system is enabled (e.g., topology generation, constraint evaluation, or reward computation, etc.). Through this, the processor 510 may be configured to implement various functions and methods described above in relation to FIGS. 1 to 11.

The memory 530 and the storage device 560 may include various types of volatile or non-volatile storage media for data storing and access of the system. For example, the memory 530 may include a read-only memory (ROM) 531 and a random access memory (RAM) 532 (e.g., DRAM, SRAM, or flash-based modules, etc.). In some examples, the memory 530 may be embedded inside the processor 510, and in this case, a data transmission speed between the memory 530 and the processor 510 may be made very rapidly. In some other examples, the memory 530 may be located outside the processor 510, and in this case, the memory 530 may be connected to the processor 510 through various data buses or interfaces. The connection may be made through various means, e.g., a peripheral component interconnect express (PCIe) interface or a memory controller for high-speed data transmission.

In some examples, at least some components or functions of the method and the device for machine design according to the examples may be implemented as a program or software executed by the computing device 50 or the program or software may be stored in a computer readable medium (e.g., a hard disk, SSD, USB drive, or cloud-based storage, etc.). Specifically, the computer-readable medium according to an example may have a program for executing the steps included in the implementation of the method and the device for machine design according to the examples recorded in a computer including a processor 510 executing a program or an instruction stored in a memory 530 or a storage device 560 (e.g., via embedded firmware, installable software packages, or downloadable modules, etc.).

In some examples, at least some components or functions of the method and the device for machine design according to the examples may be implemented by using a hardware or a circuit of the computing device 50, or implemented as a separate hardware or circuit which may be electrically connected to the computing device 50 (e.g., FPGA-based design units, custom ASICs, or coprocessor boards, etc.).

An example of the present disclosure provides a machine design method of generating gear train topology based on deep reinforcement learning, which may include: defining a Markov decision process (MDP) for applying gear train topology to reinforcement learning; expressing synthesis of the gear train topology with the MDP; and synthesizing the gear train topology through deep reinforcement learning of a deep Q-network (DQN).

In some examples, the defining the MDP may include defining adding an edge to a graph as an action, defining a state expressed by a graph generated by the action, and defining a partial score indicating whether a condition assigned in relation to a gear train topology graph is satisfied as a reward.

In some examples, in the graph, a node may represent a component, and the edge may represent a connection type.

In some examples, the state may be expressed as a state tensor defined from a state space.

In some examples, the expressing the synthesis of the gear train topology with the MDP may include switching and expressing a structure synthesis problem into a tree search problem.

In some examples, a Q-network of the DQN may be implemented to alternately use a plurality of convolutional layers and ReLU activation functions, and then apply a fully connected layer last.

In some examples, an input of the Q-network may be a tensor of the graph transformed into the state tensor, and an output of the Q-network may define an edge vector in the form of a one-hot vector.

In some examples, in the Q-network, the input may go through a first convolutional layer after passing through a first ReLU activation function, go through a second convolutional layer after passing through a second ReLU activation function, go through a third convolutional layer after passing through a third ReLU activation function, and go through the fully connected layer after passing through a fourth ReLU activation function.

In some examples, in the deep reinforcement learning, the action may include adding the edge vector corresponding to the one-hot vector to the graph.

In some examples, the synthesizing the gear train topology may include classifying the gear train topology graph generated by the deep reinforcement learning into one or more types according to a predetermined classification criterion, and generating a gear train schematic diagram according to the type of gear train topology graph.

Another example of the present disclosure provides a machine design device of generating gear train topology based on deep reinforcement learning, which may include: a storage medium configured to store computer-readable instructions; and one or more processors configured to execute the instructions to perform operations, the operations comprising: defining a Markov decision process (MDP) for applying gear train topology to reinforcement learning; expressing synthesis of the gear train topology with the MDP; and synthesizing the gear train topology through deep reinforcement learning of a deep Q-network (DQN).

In some examples, the defining the MDP may include defining adding an edge to a graph as an action, defining a state expressed by a graph generated by the action, and defining a partial score indicating whether a condition assigned in relation to a gear train topology graph is satisfied as a reward.

In some examples, in the graph, a node may represent a component, and the edge may represent a connection type.

In some examples, the state may be expressed as a state tensor defined from a state space.

In some examples, the expressing the synthesis of the gear train topology with the MDP may include switching and expressing a structure synthesis problem into a tree search problem.

In some examples, a Q-network of the DQN may be implemented to alternately use a plurality of convolutional layers and ReLU activation functions, and then apply a fully connected layer last.

In some examples, an input of the Q-network may be a tensor of the graph transformed into the state tensor, and an output of the Q-network may define an edge vector in the form of a one-hot vector.

In some examples, in the Q-network, the input may go through a first convolutional layer after passing through a first ReLU activation function, go through a second convolutional layer after passing through a second ReLU activation function, go through a third convolutional layer after passing through a third ReLU activation function, and go through the fully connected layer after passing through a fourth ReLU activation function.

In some examples, in the deep reinforcement learning, the action may include adding the edge vector corresponding to the one-hot vector to the graph.

In some examples, the synthesizing the gear train topology may include classifying the gear train topology graph generated by the deep reinforcement learning into one or more types according to a predetermined classification criterion, and generating a gear train schematic diagram according to the type of gear train topology graph.

According to examples, in a process of configuring and synthesizing a gear train by using a graph theory based kinematic chain, an artificial intelligence system generating a machine connection structure by applying deep reinforcement learning can be provided. As a result, unlike the existing methods, this method is not limited only to a fixed shaft or a specific gear set, and various conditions including interference by mounting can be considered due to a feature through the deep reinforcement learning. In particular, there is an advantage of being capable of flexibly coping with an environment in which a distance of the shaft or the quantity of shafts varies.

Further, according to examples, there is an advantage in that it is possible to apply and extend the examples to various machine structures including a cam, a cylinder structure, etc., in addition to a gear and a rotating shaft. Due to the feature, a machine structure can be automatically generated through artificial intelligence only under a machine movement condition of an input and an output given as an initial condition, and designers can devise the structure more easily and faster. As a result, the efficiency of the design can be increased, and the quality of an output can also be enhanced.

Furthermore, a new structure can be easily devised, which can lead to promotion and innovation of structure design. Further, the designers can more easily attempt various machine structures, and as a result, creative and innovative structure devising can be activated.

While the examples of the present disclosure have been described in connection with what is presently considered to be practical examples, it is to be understood that the present disclosure is not limited to the disclosed examples. On the contrary, it is intended to cover various modifications and equivalent arrangements included within the spirit and scope of the appended claims.

What is claimed is:

1. A method performed by an apparatus, the method comprising:
defining a Markov decision process (MDP) for use in deep reinforcement learning associated with gear train topology;
representing, based on the MDP, the gear train topology;
generating the gear train topology through deep reinforcement learning of a deep Q-network (DQN); and
constructing, based on the generated gear train topology, a gear train.

2. The method of claim 1, wherein the defining of the MDP comprises:
defining an action as adding an edge to a graph,
defining a state as a graph resulting from performing the action, and
defining a weight value indicating whether a condition associated with a graph representing the gear train topology is satisfied.

3. The method of claim 2, wherein a node of the graph represents a component of the gear train, and an edge of the graph represents a type of a connection between components of the gear train, wherein the state is expressed as a state tensor defined from a state space, and wherein the state space represents graph configurations of gear train topologies.

4. The method of claim 1, wherein the generating of the gear train topology comprises:
generating, based on one or more design constraints for the gear train topology, a representation of a candidate gear train topology;
iteratively modifying the representation using a machine learning model, wherein each modification is performed based on whether the modified representation satisfies the one or more design constraints; and
outputting data representing the gear train topology that satisfies the one or more design constraints.

5. The method of claim 1, wherein the representing of the gear train topology comprises converting a structure synthesis process into a tree search process.

6. The method of claim 1, wherein the DQN is implemented to alternately use a plurality of convolutional layers and Rectified Linear Unit (ReLU) activation functions, and apply a fully connected layer.

7. The method of claim 6, wherein:
an input of the DQN comprises a tensor representing a graph of the gear train topology, wherein the tensor is transformed to a state tensor, and
an output of the DQN comprises an edge vector represented as a one-hot vector, wherein the edge vector identifies a candidate connection between components in the gear train topology.

8. The method of claim 7, wherein the input of the DQN passes through a first ReLU activation function followed by a first convolutional layer, passes through a second ReLU activation function followed by a second convolutional layer, passes through a third ReLU activation function followed by a third convolutional layer, and passes through a fourth ReLU activation function followed by a fully connected layer.

9. The method of claim 7, wherein the deep reinforcement learning comprises performing an action of adding the edge vector to the graph.

10. The method of claim 1, wherein the generating of the gear train topology comprises:
classifying, based on a predetermined classification criterion, a gear train topology graph into one or more types, wherein the gear train topology graph is generated by the deep reinforcement learning; and
generating, based on the classified type of gear train topology graph, a gear train schematic diagram.

11. An apparatus comprising:
a processor; and
a memory storing at least one instruction that, when executed by the processor communicating with the memory, is configured to cause the apparatus to:
define a Markov decision process (MDP) for use in deep reinforcement learning associated with gear train topology,
represent, based on the MDP, the gear train topology,
generate the gear train topology through deep reinforcement learning of a deep Q-network (DQN), and
construct, based on the generated gear train topology, a gear train.

12. The apparatus of claim 11, wherein the at least one instruction, when executed by the processor communicating with the memory, is configured to cause the apparatus to define the MDP by:
defining an action as adding an edge to a graph,
defining a state as a graph resulting from performing the action, and
defining a weight value indicating whether a condition associated with a graph representing the gear train topology is satisfied.

13. The apparatus of claim 12, wherein a node of the graph represents a component of the gear train, and an edge of the graph represents a type of a connection between components of the gear train, wherein the state is expressed as a state tensor defined from a state space, and wherein the state space represents graph configurations of gear train topologies.

14. The apparatus of claim 11, wherein the at least one instruction, when executed by the processor communicating with the memory, is configured to cause the apparatus to generate the gear train topology by:
generating, based on one or more design constraints for the gear train topology, a representation of a candidate gear train topology;
iteratively modifying the representation using a machine learning model, wherein each modification is performed based on whether the modified representation satisfies the one or more design constraints; and
outputting data representing the gear train topology that satisfies the one or more design constraints.

15. The apparatus of claim 11, wherein the at least one instruction, when executed by the processor communicating with the memory, is configured to cause the apparatus to represent the gear train topology by converting a structure synthesis process into a tree search process.

16. The apparatus of claim 11, wherein the DQN is implemented to alternately use a plurality of convolutional layers and Rectified Linear Unit (ReLU) activation functions, and apply a fully connected layer.

17. The apparatus of claim 16, wherein:
an input of the DQN comprises a tensor representing a graph of the gear train topology, wherein the tensor is transformed to a state tensor, and
an output of the DQN comprises an edge vector represented as a one-hot vector, wherein the edge vector identifies a candidate connection between components in the gear train topology.

18. The apparatus of claim 17, wherein the input of the DQN passes through a first ReLU activation function followed by a first convolutional layer, passes through a second ReLU activation function followed by a second convolutional layer, passes through a third ReLU activation function followed by a third convolutional layer, and passes through a fourth ReLU activation function followed by a fully connected layer.

19. A method performed by an apparatus, the method comprising:
obtaining data representing one or more design constraints for a gear train topology;
generating, based on the obtained data, a representation of a candidate gear train topology;
iteratively modifying the representation using a machine learning model, wherein each modification is performed based on whether the modified representation satisfies one or more design constraints;
outputting data representing a gear train topology that satisfies the one or more design constraints; and
constructing a gear train based on the outputted data representing the gear train topology.

20. The method of claim 19, wherein:
the representation comprises a graph having a plurality of nodes and edges, wherein each node represents a mechanical component and each edge represents a type of connection between two nodes of the plurality of nodes; and
the machine learning model comprises a neural network configured to select a modification to the graph based on whether the modified graph satisfies the one or more design constraints.
